(19) United States
(12) Patent Application Publication
(10) Pub. No.: US 2025/0298722 A1
(43) Pub. Date: Sep. 25, 2025

(54) SIMULATION SYSTEM

(71) Applicant: SCREEN Holdings Co., Ltd., Kyoto (JP)

(72) Inventor: Tsutomu SAKUYAMA, Kyoto-shi (JP)

(21) Appl. No.: 19/068,530

(22) Filed: Mar. 3, 2025

(30) Foreign Application Priority Data
Mar. 22, 2024 (JP) 2024-047271

(51) Int. Cl. G06F 11/362

(52) U.S. Cl. CPC G06F 11/362

(57) ABSTRACT

A simulation system includes a provisional simulation model, a control command value output section, and a virtual controller section. The provisional simulation model simulates the operation of a real device using provisional specifications different from control specifications of the real device. The control command value output section outputs a control command value in accordance with control software. The virtual controller section operates the provisional simulation model in accordance with the control command value. This configuration is capable of evaluating whether the control command value outputted from the control software is appropriate or not using the provisional simulation model even when the real control specifications are unknown. This allows the debugging of the control software without operating the real device.

### RELATED APPLICATIONS

This application claims the benefit of Japanese Application No. 2024-047271, filed on Mar. 22, 2024, the disclosure of which is incorporated by reference herein.

### BACKGROUND OF THE INVENTION

### Field of the Invention

The present disclosure relates to a simulation system which simulates the operation of a real device on a computer.

### Description of the Background Art

Simulation systems such as HILS (Hardware In The Loop Simulation) and SILS (Software In The Loop Simulation) have heretofore been known. These simulation systems simulate the operations of real devices using control software on a computer. The use of these simulation systems allows the debugging of the control software without operating the real devices.

A conventional simulation system is disclosed, for example, in Japanese Patent Application Laid-Open No. 2009-295126.

However, conventional simulation systems are based on the premise that the control specifications of the real devices are known. In conventional methods, a simulation model cannot be created if the control specifications of a real device are unknown. In such cases, it has been necessary to operate the real device in order to debug the control software.

### SUMMARY OF THE INVENTION

It is therefore an object of the present disclosure to provide a simulation system capable of debugging control software without operating a real device, in case the control specifications of a real device are unknown.

The present disclosure is intended for a computer-based simulation system, which comprises: a provisional simulation model for simulating the operation of a real device on a computer using a provisional specification different from a control specification of the real device; a control command value output section for outputting a control command value used for control of the real device in accordance with control software installed on a computer; a memory for storing the control command value; and a virtual controller section for operating the provisional simulation model in accordance with the control command value read from the memory.

According to the present disclosure, whether the control command value outputted in accordance with the control software is appropriate or not is evaluated based on the provisional simulation model even when the control specification of the real device is unknown. This allows the debugging of the control software without operating the real device.

Preferably, the simulation system further comprises a real controller section for controlling the real device in accordance with the control command value read from the memory.

This causes the real device and the provisional simulation model to operate based on the control command value stored in the common memory. This allows the simulation to be performed with high accuracy using the provisional simulation model.

Preferably, the real device includes a first unit with a known control specification, and a second unit with an unknown control specification; the simulation system further comprises a simulator including a first simulation model for simulating the operation of the first unit on the computer using the control specification of the first unit, and a second simulation model which is the provisional simulation model for simulating the operation of the second unit on the computer using a provisional specification different from the control specification of the second unit; and the virtual controller section operates the first simulation model and the second simulation model in accordance with the control command value read from the memory.

Thus, for the first unit with the known control specification, the debugging of the control software is performed using the first simulation model created based on the real specification. For the second unit with the unknown control specification, the debugging of the control software is performed using the second simulation model created based on the provisional specification.

Preferably, the simulation system further comprises a display section for displaying a result of simulation using the provisional simulation model.

This allows a user to visually check whether the result of simulation using the provisional simulation model is appropriate or not.

Preferably, the simulation system further comprises a parameter modification section for modifying a parameter set in the control software.

This allows the modification of the parameter set in the control software when the result of simulation using the provisional simulation model is judged to be inappropriate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing a configuration of a simulation system; and

FIG. 2 is a flow diagram showing a procedure for debugging.

### DESCRIPTION OF THE PREFERRED EMBODIMENTS

A preferred embodiment according to the present disclosure will now be described in detail with reference to the drawings.

### 1. Configuration of Simulation System

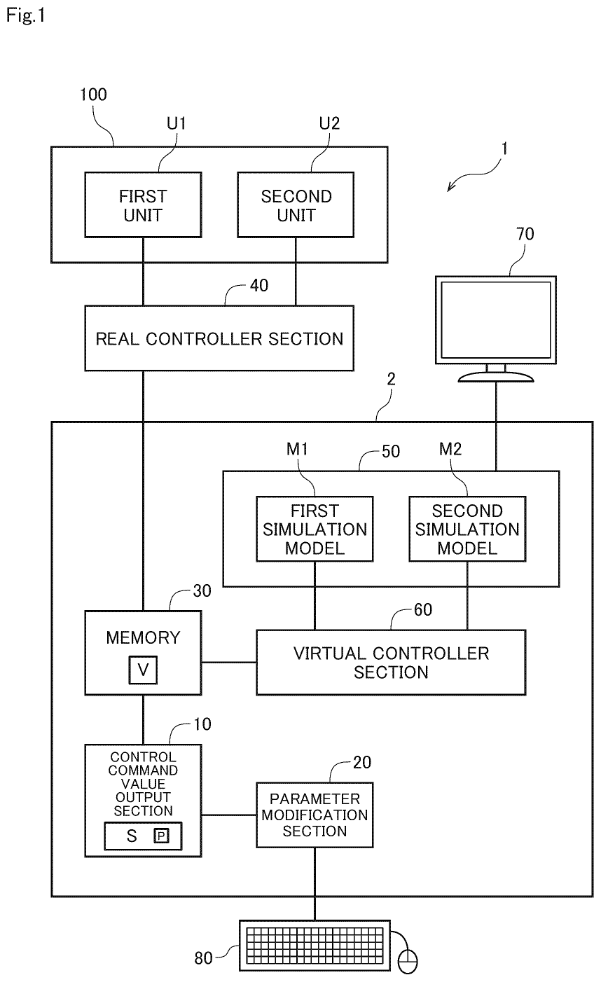

FIG. 1 is a block diagram showing a configuration of a simulation system 1 according to one preferred embodiment. This simulation system 1 is a system for simulating the operation of a real device 100 on a computer 2 in order to debug control software S which controls the real device 100. The real device 100 is an industrial machine such as a semiconductor manufacturing device, a display manufacturing device, a deposition device, and a digital printing machine. However, the real device 100 may be a device other than those described above.

As shown in FIG. 1, the simulation system 1 includes a control command value output section 10, a parameter modification section 20, a memory 30, a real controller section 40, a simulator 50, a virtual controller section 60, and a display section 70.

The control command value output section 10 is a processing section which outputs a control command value V in accordance with the control software S installed on the computer 2. The control command value V is a command value used for controlling the real device 100. For example, when a part to be controlled in the real device 100 is a robot, the control command value V includes values indicating the coordinates of the starting and ending points of the movement of the robot, the rotation angle of the robot, and the like.

The control software S has multiple parameters P set therein. The control software S outputs the control command value V in response to a parameter P. If an inappropriate parameter P is set in the control software S, the control command value V outputted from the control software S is accordingly an inappropriate value.

The parameter modification section 20 is a processing section which modifies the parameters P set in the control software S. The parameter modification section 20 modifies the parameters P of the control software S in accordance with values inputted by a user via a manipulation section 80 such as a keyboard and a mouse into the computer 2.

The memory 30 is a storage medium which stores the control command value V. The control command value V outputted from the control command value output section 10 is written to the memory 30. The memory 30 is also connected to the real controller section 40 and the virtual controller section 60 for communication therewith. The real controller section 40 and the virtual controller section 60 are capable of reading the control command value V stored in the memory 30.

The real controller section 40 is a controller which controls the operation of the real device 100. The real controller section 40 is, for example, a PLC (Programmable Logic Controller). The real controller section 40 reads the control command value V from the memory 30, and controls the operation of the real device 100 in accordance with the control command value V.

The simulator 50 is a processing section which simulates the operation of the real device 100 on the computer 2. In the present preferred embodiment, the real device 100 includes a first unit U1 and a second unit U2, as shown in FIG. 1. In corresponding relation to this, the simulator 50 includes a first simulation model M1 which simulates the operation of the first unit U1 and a second simulation model M2 which simulates the operation of the second unit U2. Each of the simulation models M1 and M2 is created using simulation software installed on the computer 2.

For the first unit U1, control specifications of the real controller section 40 are assumed to be known. In this case, the first simulation model M1 is created based on the known control specifications of the real controller section 40. The control specifications are, for example, specifications for the interface between the real controller section 40 and the first unit U1.

For the second unit U2, on the other hand, control specifications of the real controller section 40 are assumed to be unknown. In this case, the second simulation model M2 is created based on provisional specifications that differ from the control specifications (referred to hereinafter as “real specifications”) of the real controller section 40. The second simulation model M2 is an example of a “provisional simulation model”. Since the real specifications are unknown, the second simulation model M2 is created by the user of the simulation system 1 specifying provisional specifications which can reproduce the operation of the second unit U2, based on the control command value V.

The virtual controller section 60 is a controller which operates the simulator 50. The virtual controller section 60 is implemented by a CPU in the computer 2 operating in accordance with programs installed on the computer 2. The virtual controller section 60 reads the control command value V from the memory 30, and operates the first simulation model M1 and the second simulation model M2 in accordance with the control command value V.

The display section 70 is a device which displays results of simulation using the simulator 50. For example, a liquid crystal display is used for the display section 70. The display section 70 is electrically connected to the computer 2. The simulator 50 displays the result of simulation using the first simulation model M1 and the result of simulation using the second simulation model M2 on the display section 70. Specifically, the simulator 50 operates a target part in a three-dimensional model corresponding to the real device 100, based on the results of simulation. The display section 70 displays the motion of the three-dimensional model on a screen thereof.

### 2. Debugging of Control Software

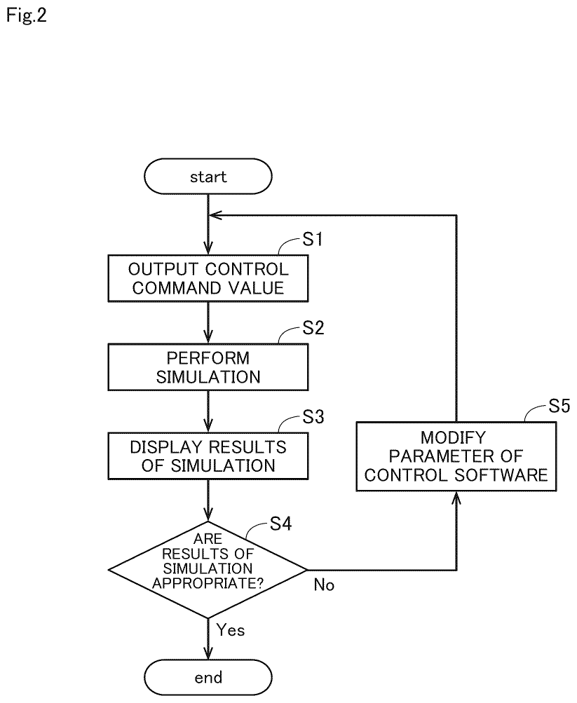

Subsequently, the debugging of the control software S using the aforementioned simulation system 1 will be described. FIG. 2 is a flow diagram showing a procedure for the debugging.

When debugging the control software S, the control command value output section 10 initially outputs the control command value V in accordance with the control software S with a parameter P set therein (Step S1), as shown in FIG. 2. In this case, the control command value V shall include a control command value V for the first unit U1 and a control command value V for the second unit U2. The control command value V outputted from the control command value output section 10 is stored in the memory 30.

Next, the virtual controller section 60 reads the control command value V from the memory 30. Then, the virtual controller section 60 operates the simulator 50, based on the control command value V (Step S2). Specifically, the virtual controller section 60 operates the first simulation model M1, based on the control command value V for the first unit U1. The virtual controller section 60 also operates the second simulation model M2, based on the control command value V for the second unit U2.

The simulator 50 displays the result of simulation using the first simulation model M1 and the result of simulation using the second simulation model M2 on the display section 70 (Step S3).

The user visually checks the results of simulation displayed on the display section 70. Then, the user judges whether the result of simulation using the first simulation model M1 and the result of simulation using the second simulation model M2 are appropriate or not (Step S4). For example, if the robot interferes with other components when moving or stops in an incorrect position in the three-dimensional model displayed on the display section 70, the user judges that the results of simulation are inappropriate.

If the results of simulation are inappropriate (No in Step S4), the user modifies the parameter P of the control software S (Step S5). For example, if the result of simulation using the first simulation model M1 is inappropriate, the user modifies the parameter P of the control software S for the first unit U1. If the result of simulation using the second simulation model M2 is inappropriate, the user modifies the parameter P of the control software S for the second unit U2.

Specifically, the user manipulates the manipulation section 80 to input a modified value for the parameter P of the control software S. In this case, the user inputs a parameter P that has been increased or decreased from the existing parameter P, based on the results of simulation. Then, the parameter modification section 20 of the computer 2 modifies the parameter P of the control software S to the inputted value.

After the parameter P of the control software S is modified, the procedure returns to Step S1, and the processes in Steps S1 to S4 are executed again. Then, the processes in Steps S1 to S5 are repeated until the results of simulation are judged to be appropriate in Step S4. Finally, when the user judges that the results of simulation are appropriate in Step S4 (Yes in Step S4), the debugging of the control software S is completed.

As described above, this simulation system 1 creates the simulation models M1 and M2 corresponding to the respective units U1 and U2 of the real device 100, and debugs the control software S, based on the results of simulation using the simulation models M1 and M2.

In particular, when the control specifications are unknown such as for the second unit U2, this simulation system 1 outputs the result of simulation using the provisional simulation model created using the provisional specifications that differ from the real specifications. In the conventional techniques, the result of simulation cannot be obtained for a unit with unknown control specifications. In addition, when the conventional techniques evaluate the control of a unit with unknown control specifications, it is only confirmed that some control command value V is outputted from the control software S. However, the simulation system 1 of the present preferred embodiment is capable of evaluating whether the control command value V written from the control software S to the memory 30 is appropriate or not for the second unit U2 with unknown control specifications.

Thus, the use of the simulation system 1 enables the debugging of the control software S prior to the manufacture of the real device 100 even when the control specifications are unknown. This achieves the optimization of the parameters P of the control software S prior to the manufacture of the real device 100.

### 3. Modifications

While the one preferred embodiment has been described hereinabove, the present disclosure is not limited to the aforementioned preferred embodiment.

In the aforementioned preferred embodiment, the real device 100 includes the two units U1 and U2. However, the number of units that the real device 100 has may be one or, not less than three.

Also, in the aforementioned preferred embodiment, the results of simulation outputted from the simulator 50 are based on the three-dimensional model. However, the results of simulation outputted from the simulator 50 may be information on a two-dimensional model, numerical values, or the like.

In the aforementioned preferred embodiment, a human user visually judges whether the results of simulation displayed on the display section 70 are appropriate or not. However, the simulator 50 may automatically output an alarm when the results of simulation are inappropriate. For example, the simulator 50 may display a warning message on the display section 70 or output a warning sound when the robot interferes with other components in a simulation model.

The control command value output section 10, the memory 30, and the virtual controller section 60 are provided in the single computer 2 in the aforementioned preferred embodiment. However, some of these sections may be provided in other computers connected via a network.

Some of the components appearing in the aforementioned preferred embodiment and modifications may be omitted or other components may be added without departing from the spirit of the present disclosure.

While the invention has been shown and described in detail, the foregoing description is in all aspects illustrative and not restrictive. It is therefore understood that numerous modifications and variations can be devised without departing from the scope of the invention.

What is claimed is:

1. A computer-based simulation system, comprising:
a provisional simulation model for simulating the operation of a real device on a computer using a provisional specification different from a control specification of said real device;
a control command value output section for outputting a control command value used for control of said real device in accordance with control software installed on a computer;
a memory for storing said control command value; and
a virtual controller section for operating said provisional simulation model in accordance with said control command value read from said memory.

2. The simulation system according to claim 1, further comprising a real controller section for controlling said real device in accordance with said control command value read from said memory.

3. The simulation system according to claim 1,
wherein said real device includes
a first unit with a known control specification, and
a second unit with an unknown control specification, said simulation system further comprising
a simulator including
a first simulation model for simulating the operation of said first unit on the computer using the control specification of said first unit, and
a second simulation model which is said provisional simulation model for simulating the operation of said second unit on the computer using a provisional specification different from the control specification of said second unit,
wherein said virtual controller section operates said first simulation model and said second simulation model in accordance with said control command value read from said memory.

4. The simulation system according to claim 1, further comprising
a display section for displaying a result of simulation using said provisional simulation model.

5. The simulation system according to claim 1, further comprising
a parameter modification section for modifying a parameter set in said control software.
